(19) United States
(12) Patent Application Publication
(10) Pub. No.: US 2010/0013539 A1
(43) Pub. Date: Jan. 21, 2010

(54) COMMUNICATION CIRCUIT WITH SELECTABLE SIGNAL VOLTAGE

(75) Inventor: David Novak, Westfield, IN (US)

Correspondence Address: FLETCHER YODER P.C., 7915 FM 1960 RD. WEST, SUITE 330, HOUSTON, TX, 77070, US

(73) Assignee: TTE Technology, Inc., Indianapolis, IN (US)

(21) Appl. No.: 12/294,582

(22) PCT Filed: Mar. 30, 2006
(86) PCT No.: PCT/US06/12635

§ 371 Date: Jun. 16, 2009

(51) Int. Cl. H03L 5/00

(52) U.S. Cl. 327/333

(57) ABSTRACT

The disclosed embodiments relate to a communication circuit. An exemplary embodiment of the communication circuit comprises a first branch adapted to operate at a first signal voltage level, a first source voltage contact adapted to deliver a voltage corresponding to the first signal voltage level to the first branch, a second branch adapted to operate at a second signal voltage level that is higher than the first signal voltage level, a second source voltage contact adapted to receive a voltage corresponding to the second signal voltage level via an external connector and to deliver the voltage corresponding to the second signal voltage level to the second branch, and a voltage selection circuit coupled to the first source voltage contact and the second source voltage contact, the voltage selection circuit configured to provide the first signal voltage level to the first branch and the second signal voltage level to the second branch.

### CROSS-REFERENCE TO RELATED APPLICATIONS

This application is a National Phase 371 Application of PCT Application No. PCT/US06/12635, filed Mar. 30, 2006, entitled “Communication Circuit With Selectable Signal Voltage”.

### FIELD OF THE INVENTION

The present invention relates to improving the interconnectivity of integrated circuit components, such as devices capable of communicating via an Inter-Integrated Circuit (I²C) bus.

### BACKGROUND OF THE INVENTION

This section is intended to introduce the reader to various aspects of art which may be related to various aspects of the present invention which are described and/or claimed below. This discussion is believed to be helpful in providing the reader with background information to facilitate a better understanding of the various aspects of the present invention. Accordingly, it should be understood that these statements are to be read in this light, and not as admissions of prior art.

Many electronics systems employ communication schemes to allow communication between various system components such as integrated circuit devices. An example of such a communication scheme is the I²C bus developed by Royal Philips Electronics N.V. The I²C bus is a serial communication link that is employed to attach low-speed peripherals to a motherboard, an embedded system or the like. Examples of applications for the I²C bus include accessing non-volatile random access memory (NVRAM) chips that store user settings, accessing low speed digital-to-analog convertors (DACs) and analog-to-digital convertors (ADCs), changing settings on computer monitors, reading hardware monitors and diagnostic sensors, and the like.

Communication via the I²C bus involves two lines: a clock line (SCL) and a data line (SDA). Except for the beginning and end of transmissions, the SDA line changes state when the SCL line is low. The SDA line is sampled when the SCL line goes high. There are special SDA/SCL sequences to signify the start and the end (stop) of transmissions. A single bus master has the ability to toggle the SCL line, but subordinate devices have the ability to stretch the clock by holding the SCL line low when more time is needed.

The devices on an I²C bus operate as open drain devices, which are tied via a pull-up resistor to a voltage source corresponding to a signal voltage level. The signal voltage level should not exceed the maximum input voltage requirements of the ICs connected to the I²C bus.

Operational problems can arise when the I²C bus is extended beyond a single printed circuit board (PCB) and connected to external circuitry. One such problem may occur when the external circuitry requires logic voltage levels that are greater than the ICs on the PCB can tolerate. For instance, if the external device requires 5 volt logic levels, but none of the ICs on the PCB can tolerate greater than 3.3 volts, connecting the I²C bus to the external device and the PCB could result in damage to the ICs on the PCB.

Previously, this voltage mismatch issue has been addressed by including a voltage translation circuit such as a FET circuit on the PCB to operate the external interface section of the I²C bus at 5-volt logic levels. However, the conversion of the bus signals from 3.3 volt levels to 5 volt levels has been known to cause non-monotonic behavior during the signal transitions. This non-monotonic behavior can cause false clock edges, which could corrupt I²C bus traffic.

The use of a prior art voltage translation circuit to address a voltage level mismatch on an I²C bus creates system performance problems. A system and method that reduces the negative effects of such a voltage level mismatch is desirable.

### SUMMARY OF THE INVENTION

The disclosed embodiments relate to a communication circuit. An exemplary embodiment of the communication circuit comprises a first branch adapted to operate at a first signal voltage level, a first source voltage contact adapted to deliver a voltage corresponding to the first signal voltage level to the first branch, a second branch adapted to operate at a second signal voltage level that is higher than the first signal voltage level, a second source voltage contact adapted to receive a voltage corresponding to the second signal voltage level via an external connector and to deliver the voltage corresponding to the second signal voltage level to the second branch, and a voltage selection circuit coupled to the first source voltage contact and the second source voltage contact, the voltage selection circuit configured to provide the first signal voltage level to the first branch and the second signal voltage level to the second branch.

### BRIEF DESCRIPTION OF THE DRAWINGS

In the drawings:

FIG. 1 is schematic diagram of a communication circuit in accordance with an exemplary embodiment of the present invention; and

FIG. 2 is a flow chart of a process in accordance with an exemplary embodiment of the present invention.

### DETAILED DESCRIPTION OF THE PREFERRED EMBODIMENT

This section is intended to introduce the reader to various aspects of art which may be related to various aspects of the present invention which are described and/or claimed below. This discussion is believed to be helpful in providing the reader with background information to facilitate a better understanding of the various aspects of the present invention. Accordingly, it should be understood that these statements are to be read in this light, and not as admissions of prior art.

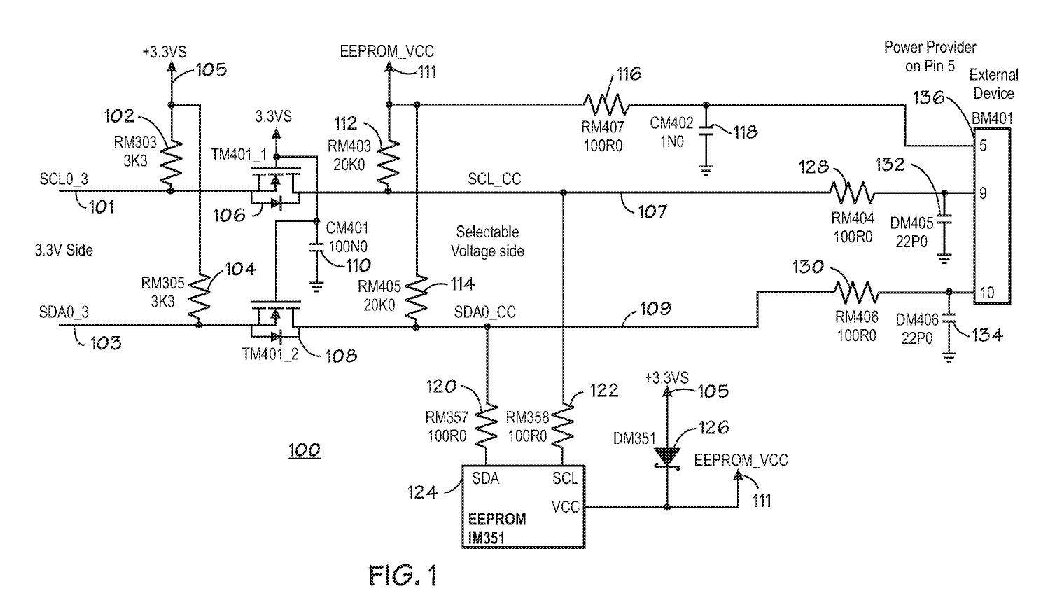

FIG. 1 is schematic diagram of a communication circuit in accordance with an exemplary embodiment of the present invention. The communication circuit is generally referred to by the reference number 100. As set forth below, exemplary embodiments of the present invention operate to automatically select a signal voltage level for different branches of the communication circuit 100. By way of example, the communication circuit 100 illustrated in FIG. 1 comprises two separate branches. The first branch comprises a clock line 101 (SCL0_3) and a data line 103 (SDA0_3). The clock line 101 is connected by a pull-up resistor 102 to a source voltage contact 105 (+3.3 VS), which is indicated to be about 3.3 volts in the exemplary embodiment shown in FIG. 1. The data line 103 is connected via a pull-up resistor 104 to the source voltage contact 105. The first branch is identified as the “3.3V side” in FIG. 1.

The second branch of the communication circuit 100 comprises a clock line 107 (SCL_CC) and a data line 109 (SDA_CC). A transition circuit 106 connects the clock line 101 of the first branch with the clock line 107 of the second branch. A transition circuit 108 connects the data line 103 of the first branch with the data line 109 of the second branch. The transition circuits 106 and 108 may each comprise a field effect transistor (FET). The transition circuits 106 and 108 are connected to a system ground via a filter capacitor 110. The clock line 107 is connected to a source voltage contact 111 (EEPROM_VCC) via a pull-up resistor 112. The data line 109 is connected to the source voltage contact 111 (EEPROM_VCC) via a pull-up resistor 114.

The source voltage contact 111 is also connected to provide power to an EEPROM 124. The EEPROM 124 has a data output (SDA), which is connected to the data line 109 via a resistor 120, and a clock output (SCL), which is connected to the clock line 107 via a resistor 122. In this manner, the EEPROM may provide clock and data signals for the communication circuit 100.

In an exemplary embodiment of the present invention, the source voltage contact 105 is isolated from the source voltage contact 111. The value of a signal voltage level in the first branch of the communication circuit 100 corresponds to the value of the voltage supplied to the source voltage contact 105. The signal voltage value determines the voltage range of signal values that will be interpreted as a logical “0” or a logical “1” in that branch of the circuit. In the first branch of the communication circuit 100, 3.3 volts is the maximum allowable voltage for a signal. This means that 3.3 volts is the top of the range for determining whether a signal is a logical “0” or a logical “1” in the first branch of the communication circuit 100.

The value of a signal voltage level in the second branch of the communication circuit 100 corresponds to the value of a voltage delivered to the source voltage contact 111. In one exemplary embodiment of the present invention, voltage is delivered to the source voltage contact 111 via an external connector when an external device is connected to the communication circuit 100. As explained below, the value of the externally provided signal voltage level may be higher than the voltage provided to the source voltage contact 105 of the first branch of the communication circuit 100. For example, the value of the voltage at the source voltage contact 111 may be in the range of about 5.0 volts. This means that 5.0 volts is the top of the range for determining whether a signal is a logical “0” or a logical “1” in the second branch of the communication circuit 100.

If no external device is connected to the communication circuit 100 via the connector 136, the source voltage contact 111 may be connected to the source voltage contact 105. In that case, the values of the signal voltage levels in the first and second branches of the communication circuit 100 are the same.

As noted, an exemplary embodiment of the present invention is adapted to allow connection of an external device needing a higher signal voltage level than the signal voltage level provided in the first branch of the communication circuit 100. For example, a device requiring a signal voltage value of about 5 volts may be connected via the external connector 136. An exemplary embodiment of the present invention is adapted to recognize that a higher signal voltage level is needed in the second branch of the circuit relative to the first branch of the circuit and to accommodate this need without difficulty.

The external connector 136 includes a signal path that provides a voltage to the source voltage contact 111 via a resistor 116. That signal path is labeled as pin “5” of the connector 136 in FIG. 1. The voltage provided via this connection sets the signal voltage level for the second branch of the communication circuit 100.

The clock signal 107 and the data signal 109 may be provided to the external device connected via the connector 136 respectively through a resistor 128 and a resistor 130. The clock signal 107 is grounded via a filter capacitor 132 and the data signal 109 is grounded via a filter capacitor 134.

In addition to providing operating voltage for the EEPROM 124, the source voltage contact 111 is connected through a cathode of a diode 126 to the source voltage contact 105 associated with the first branch of the communication circuit 100. The diode 126 is placed in the supply line to all integrated circuit devices on the selectable voltage side (the second branch) of the communications circuit 100. The source voltage contact 111 is also connected as a pull-up voltage for the I²C bus in the second branch of the communication circuit 100. In this manner, the voltage provided to the source voltage contact 111 is employed to set the signal voltage level in the second branch of the communication circuit 100.

Thus, the communication circuit 100 can accommodate external devices that operate at a signal level of about 3.3 volts up to any reasonable level, such as, for example, about 5 volts. If the signal voltage level of the external device is about 3.3 volts (i.e., the same as the signal level in the first branch of the circuit), the voltage drop across the diode 126 is negligible. If, however, the external device requires higher levels (e.g., in the range of about 5.0 volts), the diode 126 acts to drop the difference in voltage between the second signal voltage level delivered to the source voltage contact 111 and the first signal voltage level delivered to the source voltage contact 105.

An exemplary embodiment of the invention, as illustrated in FIG. 1, has the ability to allow an external device to select its desired communication voltage level without the necessity of a low-to-high logic level conversion. Undesirable non-monotonic effects when no external device is connected are minimized by receiving the second signal voltage level from the external device via the connector 136 rather than permanently pulling the signal level on the selectable side to a higher level such as 5 volts. An exemplary embodiment of the present invention allows a single product design to support multiple external devices, each requiring different logic voltage levels.

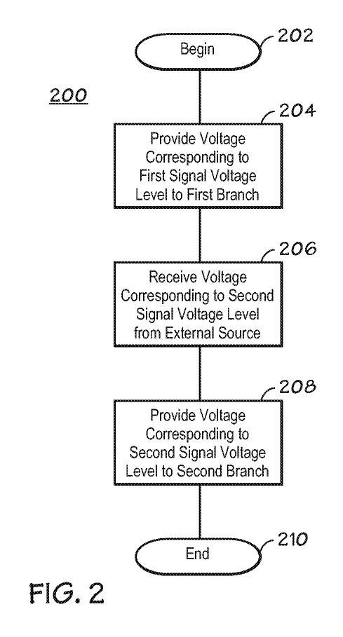

FIG. 2 is a flow chart of a process in accordance with an exemplary embodiment of the present invention. The process is generally referred to by the reference number 200. At block 202, the process begins.

At block 204, a voltage corresponding to a first signal voltage level is provided to a first branch of a communication circuit. In an exemplary embodiment of the present invention, the first signal voltage level is lower than a second signal voltage level associated with an external device that is to be connected to the communication circuit. At block 206, an external voltage corresponding to the second signal voltage level is received from an external source via, for example, an external connector such as the external connector 136 illustrated in FIG. 1. At block 208, a voltage corresponding to the second signal voltage level is provided to a second branch of the communication circuit. At block 210, the process ends.

While the invention may be susceptible to various modifications and alternative forms, specific embodiments have been shown by way of example in the drawings and will be described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A communication circuit, comprising:
a first branch adapted to operate at a first signal voltage level;
a first source voltage contact adapted to deliver a voltage corresponding to the first signal voltage level to the first branch;
a second branch adapted to operate at a second signal voltage level that is higher than the first signal voltage level;
a second source voltage contact adapted to receive a voltage corresponding to the second signal voltage level via an external connector and to deliver the voltage corresponding to the second signal voltage level to the second branch; and
a voltage selection circuit coupled to the first source voltage contact and the second source voltage contact, the voltage selection circuit configured to provide the first signal voltage level to the first branch and the second signal voltage level to the second branch.

2. The communication circuit recited in claim 1, wherein the first branch comprises a clock line.

3. The communication circuit recited in claim 1, wherein the first branch comprises a data line.

4. The communication circuit recited in claim 1, wherein the communication circuit comprises an Inter-Integrated Circuit (I²C) bus.

5. The communication circuit recited in claim 1, wherein the voltage selection circuit comprises a diode.

6. The communication circuit recited in claim 1, wherein the first signal voltage level is about 3.3 volts.

7. The communication circuit recited in claim 1, wherein the second signal voltage level is about 5.0 volts.

8. The communication circuit recited in claim 1, comprising a transition circuit that connects the first branch and the second branch.

9. The communication circuit recited in claim 8, wherein the transition circuit comprises a first field effect transistor (FET) circuit and a second FET circuit.

10. The communication circuit recited in claim 1, wherein the second signal voltage level is supplied to the second branch via at least one pull-up resistor.

11. A method of selecting a signal voltage level in a communication circuit that includes a first branch and a second branch, the method comprising:
providing a first signal voltage level to the first branch;
receiving a voltage corresponding to a second signal voltage level from a source external to the communication circuit, the voltage corresponding to the second signal voltage level being greater than the first signal voltage level; and
providing the second signal voltage level to the second branch.

12. The method recited in claim 11, comprising receiving a clock signal via a clock line.

13. The method recited in claim 11, comprising receiving a data signal via a data line.

14. The method recited in claim 11, comprising communicating over the communication circuit according to an Inter-Integrated Circuit (I²C) bus protocol.

15. The method recited in claim 11, wherein the first signal voltage level is about 3.3 volts.

16. The method recited in claim 11, wherein the second signal voltage level is about 5.0 volts.

17. A communication circuit adapted to select a signal voltage level, the communication circuit including a first branch adapted to operate at a first signal voltage level and a second branch adapted to operate at a second signal voltage level, the second signal voltage level being greater than the first signal voltage level, the communication circuit comprising:
means for providing a voltage corresponding to the first signal voltage level to the first branch;
means for receiving a voltage corresponding to the second signal voltage level from a source external to the communication circuit; and
means for providing the second signal voltage to the second branch.

18. The communication circuit recited in claim 17, wherein the communication circuit comprises a clock line.

19. The communication circuit recited in claim 17, wherein the communication circuit comprises a data line.

20. The communication circuit recited in claim 17, wherein the communication circuit comprises an Inter-Integrated Circuit (I²C) bus.
